(19) United States
(12) Patent Application Publication
(10) Pub. No.: US 2026/0082821 A1
(43) Pub. Date: Mar. 19, 2026

(54) Superconductor Device and Method for Production Thereof

(71) Applicant: NEC Corporation, Minato-ku, Tokyo (JP)

(72) Inventors: Suguru WATANABE, Tokyo (JP); Katsumi KIKUCHI, Tokyo (JP); Kunihiko ISHIHARA, Tokyo (JP)

(73) Assignee: NEC Corporation, Minato-ku, tokyo (JP)

(21) Appl. No.: 18/829,719

(22) Filed: Sep. 10, 2024

(30) Foreign Application Priority Data
Sep. 29, 2023 (JP) 2023-169716

(51) Int. Cl. H10N 60/81; H01R 13/24

(52) U.S. Cl. CPC H10N 60/81; H01R 13/2421

(57) ABSTRACT

A superconductor device provided with a superconductor circuit chip; a multi-layer board including multiple wiring layers; and multiple pins electrically connecting the superconductor circuit chip with the multi-layer board; wherein the multiple pins are inserted into a wiring layer of the multi-layer board in a direction intersecting the wiring layer. Additionally, a superconductor device provided with a superconductor circuit chip; a multi-layer board including multiple wiring layers; an interposer that is disposed between the multi-layer board and the superconductor circuit chip, that is electrically connected to the superconductor circuit chip, and that has a wiring layer connected to a wiring layer of the wiring layers; and multiple pins electrically connecting the interposer with the multi-layer board; wherein the multiple pins are inserted into at least one of the wiring layer in the multi-layer board and in the interposer in a direction intersecting the wiring layer.

This application is based upon and claims the benefit of priority from Japanese patent application No. 2023-169716, filed Sep. 29, 2023, the disclose of which is incorporated herein in its entirety by reference.

### TECHNICAL FIELD

The present disclosure relates to a superconductor device and a method for production thereof.

### BACKGROUND ART

In superconductor devices formed by mounting a superconductor circuit chip making use of quantum states on a circuit board, the electrical connections between the circuit board, etc. and the superconductor circuit chip (or an interposer on which the superconductor circuit chip is mounted) are required to be highly reliable in the low-temperature environments for realizing superconductive states. Patent Document 1 (Japanese Unexamined Patent Application Publication No. Sho 58-030079) discloses technology pertaining to electrical connections between a circuit board, etc. and a wiring layer of a superconductor circuit chip.

That is, in Patent Document 1, mercury spheres are interposed between micropins connected to the circuitry in the superconductor circuit chip and micropins connected to a wiring module board, and the connections between the superconductor circuit chip and the wiring module are maintained by the mercury spheres deforming in accordance with the relative displacement between the micropins associated with temperature changes.

### SUMMARY

An example of an objective of the present disclosure is to connect components of a superconductor device without using mercury.

In order to solve the above-mentioned problems, the present disclosure proposes the subject matter below.

A superconductor device according to a first example embodiment of the present disclosure is a device that makes use of superconductive properties, comprising: a superconductor circuit chip in which a functional circuit is provided; a multi-layer board including multiple wiring layers; and multiple pins electrically connecting the superconductor circuit chip with the multi-layer board; wherein the multiple pins are inserted into a wiring layer of the multiple wiring layers in the multi-layer board in a direction intersecting the wiring layer.

A superconductor device according to a second example embodiment of the present disclosure is a device that makes use of superconductive properties, comprising: a superconductor circuit chip in which a functional circuit is provided; a multi-layer board including multiple wiring layers; an interposer that is disposed between the multi-layer board and the superconductor circuit chip, that is electrically connected to the superconductor circuit chip, and that has a wiring layer connected to a wiring layer of multiple wiring layers in the multi-layer board; and multiple pins electrically connecting the interposer with the multi-layer board; wherein the multiple pins are inserted into at least one of the wiring layer in the multi-layer board and the wiring layer in the interposer in a direction intersecting the wiring layer.

A method for producing a superconductor device according to a third example embodiment of the present disclosure is a method for producing a superconductor device in which a superconductor circuit chip provided with a functional circuit that makes use of superconductive properties and a multi-layer board including multiple wiring layers are electrically connected by multiple pins, wherein: the multiple pins are inserted into a wiring layer of the multiple wiring layers in the multi-layer board in a direction intersecting the wiring layer, thereby deforming the wiring layer.

A method for producing a superconductor device according to a fourth example embodiment of the present disclosure is a method for producing a superconductor device in which an interposer electrically connected to a superconductor circuit chip provided with a functional circuit that makes use of superconductive properties and a multi-layer board including multiple wiring layers are electrically connected by multiple pins, wherein: the multiple pins are inserted into at least one of a wiring layer of the multiple wiring layers in the multi-layer board and a wiring layer in the interposer in a direction intersecting the wiring layer, thereby deforming the wiring layer.

### BRIEF DESCRIPTION OF THE DRAWINGS

FIG. 1A is a section view illustrating a minimum configuration example of a superconductor device according to the present disclosure, illustrating an example of a connection between a superconductor circuit chip and a multi-layer board.

FIG. 1B is a section view illustrating a minimum configuration example of a superconductor device according to the present disclosure, illustrating an example of a connection between an interposer and a multi-layer board.

FIG. 2A is a section view illustrating a superconductor device according to a first example embodiment of the present disclosure.

FIG. 2B is a section view of a modified example illustrating a superconductor device according to the first example embodiment of the present disclosure.

FIG. 3 is a vertical section view of a pin illustrated in FIG. 2A and FIG. 2B.

FIG. 4 is a section view of a superconductor device according to a second example embodiment of the present disclosure.

FIG. 5 is a section view of a superconductor device according to a third example embodiment of the present disclosure.

FIG. 6 is a section view of a superconductor device according to a fourth example embodiment of the present disclosure.

FIG. 7 is a section view of a superconductor device in a comparative example with respect to the first example embodiment to the fourth example embodiment.

FIG. 8A is a vertical section view of basic form 1, illustrating a modified example of the pins used in the first example embodiment to the fourth example embodiment.

FIG. 8B is a vertical section view of basic form 2, illustrating a modified example of the pins used in the first example embodiment to the fourth example embodiment.

FIG. 8C is a vertical section view of modified example 1, illustrating a modified example of the pins used in the first example embodiment to the fourth example embodiment.

FIG. 8D is a vertical section view of modified example 2, illustrating a modified example of the pins used in the first example embodiment to the fourth example embodiment.

FIG. 8E is a vertical section view of modified example 3, illustrating a modified example of the pins used in the first example embodiment to the fourth example embodiment.

FIG. 8F is a vertical section view of modified example 4, illustrating a modified example of the pins used in the first example embodiment to the fourth example embodiment.

FIG. 9 is a plan view illustrating the basic form and modified example 1 to modified example 11 of holes in pin insertion portions used in the first example embodiment to the fourth example embodiment.

FIG. 10 is a plan view illustrating the basic form and modified example 1 to modified example 11 of plated holes in pin insertion portions used in the first example embodiment to the fourth example embodiment.

FIG. 11 is a side view of a pin with the basic shape in a pin used in the first example embodiment to the fourth example embodiment.

FIG. 12 is an arrow view along the line XII-XII in FIG. 11 for the basic shape and the modified examples 1 to 11 of the pin illustrated in FIG. 11.

FIG. 13 is a side view of a pin with the basic shape used in the first example embodiment 1 to the fourth example embodiment.

FIG. 14 is a diagram illustrating side-view shapes of the basic shape and the modified examples 1 to 8 of the pin viewed in the direction of the arrow XIV in FIG. 13.

FIG. 15 is a section view of a superconductor device according to a fifth example embodiment of the present disclosure.

FIG. 16 is a section view of a superconductor device according to a sixth example embodiment of the present disclosure.

FIG. 17 is a partial plan view illustrating the positional relationship between a recess and a superconductor circuit chip in the superconductor device illustrated in FIG. 16.

FIG. 18 is a section view of a superconductor device according to a seventh example embodiment of the present disclosure.

FIG. 19 is a section view of a superconductor device according to an eighth example embodiment of the present disclosure.

### EXAMPLE EMBODIMENTS

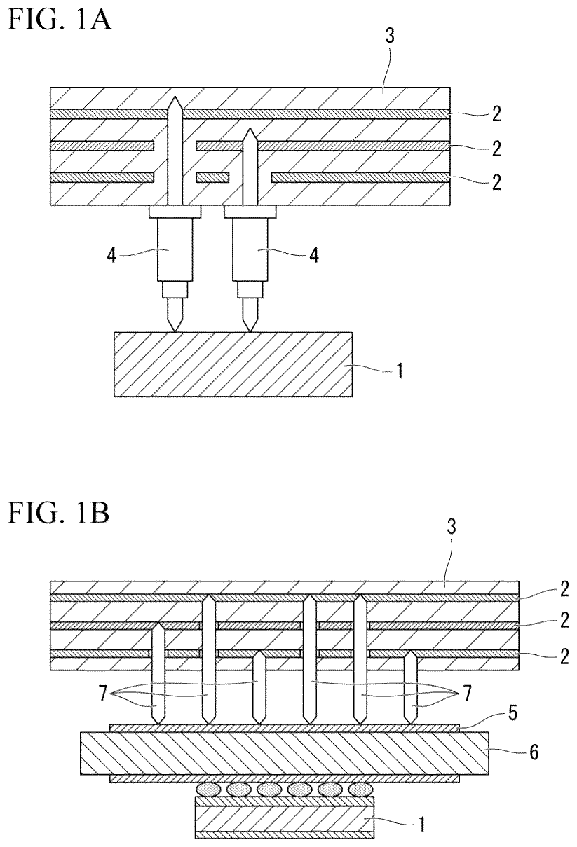

A superconductor device according to a minimum configuration example of the present disclosure will be explained with reference to FIG. 1A and FIG. 1B.

The superconductor device illustrated in FIG. 1A is a device that makes use of superconductive properties, comprising a superconductor circuit chip 1 in which a functional circuit is provided; a multi-layer board 3 including multiple wiring layers 2; and multiple pins 4 electrically connecting the superconductor circuit chip 1 with the multi-layer board 3; wherein the pins 4 are inserted in the wiring layers 2 of the multi-layer board 3 in a direction intersecting the wiring layers 2.

The superconductor device illustrated in FIG. 1B is a device that makes use of superconductive properties, comprising: a superconductor circuit chip 1 in which a functional circuit is provided; a multi-layer board 3 including multiple wiring layers 2; an interposer 6 that is disposed between the multi-layer board 3 and the superconductor circuit chip 1, that is electrically connected to the superconductor circuit chip 1, and that has a wiring layer 5 connected to the wiring layers 2 in the multi-layer board 3; and multiple pins 7 electrically connecting the interposer 6 with the multi-layer board 3; wherein the pins 7 are inserted in at least one of the wiring layers 2 of the multi-layer board 3 and the wiring layer 5 in the interposer 6, in a direction intersecting these.

In the superconductor device illustrated in FIG. 1A, by inserting the upper ends of the pins 4 into the multi-layer board 3 in the direction orthogonal thereto, the upper ends of the pins 4 penetrate through while deforming the wiring layers 2, and at the penetration locations, enter a tight contact state with and are electrically connected to the wiring layers 2. Since the pins 4 plastically deform and penetrate through portions of the wiring layers 2 and also penetrate therethrough with partial elastic deformation, the plastic deformation of a metal making up the wiring layers 2 allows a large contact area required for electrical connection to be secured and also allows tight contact to be made by means of stress generated in the elastically deformed wiring layers 2. Therefore, the pins 4 allow the reliability of electrical connections with the wiring layers 2 to be increased between the superconductor circuit chip 1 and the multi-layer board 3.

In the superconductor device illustrated in FIG. 1B, by inserting the upper ends of the pins 7 into the wiring layers 2 of the multi-layer board 3 in the direction orthogonal thereto, the upper ends of the pins 7 penetrate through while deforming the wiring layers 2, and at the penetration locations, enter a tight contact state with and are electrically connected to the wiring layers 2. Additionally, the lower ends of the pins 7 are inserted into, while deforming, a wiring layer 5 in the interposer 6. Since the pins 7 plastically deform and penetrate through portions of the wiring layers 2 and 5, and also penetrate therethrough while causing elastic deformation at other portions, the plastic deformation of a metal making up the wiring layers 2 and 5 allows a large contact area to be secured, and also allows tight contact to be made by means of stress generated in the elastically deformed wiring layers 2, 5. Therefore, the pins 7 allow the reliability of electrical connections with the wiring layers 2 and/or 5 to be increased between the multi-layer board 3 and the interposer 6.

Additionally, one method for producing a superconductor device according to a minimum configuration example of the present disclosure, as illustrated in FIG. 1A, is a method for producing a superconductor device in which a superconductor circuit chip 1 provided with a functional circuit that makes use of superconductive properties and a multi-layer board 3 including multiple wiring layers 2 are electrically connected by multiple pins 4, wherein: the pins 4 are inserted into wiring layers 2 in the multi-layer board 3 in a direction intersecting the wiring layers 2, thereby deforming the wiring layers 2.

Additionally, another method for producing a superconductor device according to a minimum configuration example of the present disclosure is a method for producing a superconductor device in which an interposer 6 electrically connected to a superconductor circuit chip 1 provided with a functional circuit that makes use of superconductive properties and a multi-layer board 3 including multiple wiring layers 2 are electrically connected by multiple pins 7, wherein: the pins 7 are inserted into at least one of a wiring layer 2 in the multi-layer board 3 and a wiring layer 5 in the interposer 6 in a direction intersecting the wiring layers 2, 5, thereby deforming the wiring layers 2, 5.

According to the production methods with the above-mentioned configuration, by inserting the upper ends of the pins 4 into the multi-layer board 3 in the direction orthogonal thereto, the upper ends of the pins 4 penetrate through while deforming the wiring layers 2, and at the penetration locations, enter a tight contact state with and are electrically connected to the wiring layers 2. The pins 4 plastically deform and penetrate through portions of the wiring layers 2 and also penetrate while causing elastic deformation in other portions. Therefore, the plastic deformation of a metal making up the wiring layers 2 allows a large contact area to be secured and also allows tight contact to be made by means of stress generated in the elastically deformed wiring layers 2, and allows the reliability of electrical connections with the wiring layers 2 to be increased between the superconductor circuit chip 1 and the multi-layer board 3.

Additionally, by inserting the upper ends of the pins 7 into the wiring layers 2 of the multi-layer board 3 in the direction orthogonal thereto, the upper ends of the pins 7 penetrate through while deforming the wiring layers 2, and at the penetration locations, enter a tight contact state with and are electrically connected to the wiring layers 2. Additionally, since the lower ends of the pins 7 penetrate through, while deforming, the wiring layer 5 in the interposer 6, the pins 7 plastically deform and penetrate through portions of the wiring layers 2 and 5, and also penetrate therethrough while causing elastic deformation at other portions. Therefore, the plastic deformation of a metal making up the wiring layers 2 and 5 allows a large contact area to be secured, and also allows tight contact to be made by means of stress generated in the elastically deformed wiring layers 2, 5. Therefore, the reliability of electrical connections with the wiring layers 2 and/or 5 can be increased between the multi-layer board 3 and the interposer 6.

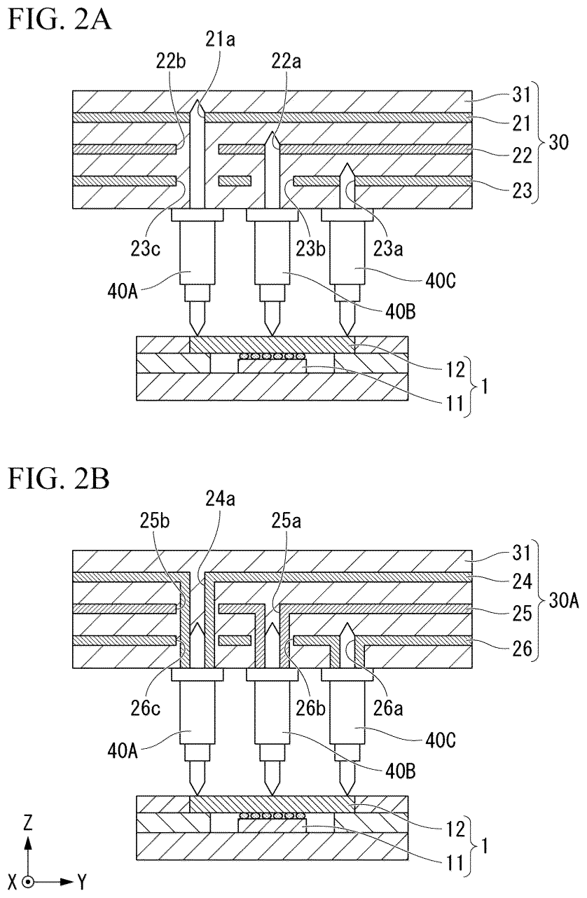

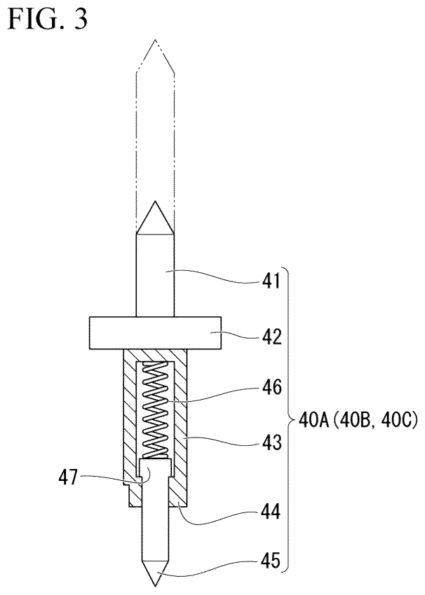

FIG. 2A, FIG. 2B, and FIG. 3 illustrate a first example embodiment of the present disclosure.

The superconductor device of the first example embodiment has a basic structure in which a superconductor circuit chip 1 and a multi-layer board 30 are connected by pins 40A, 40B, and 40C. In the first to eighth example embodiments explained below, the superconductor circuit chip refers to an element provided with the function of processing data by using quantum mechanical phenomena due to quantum bits formed by the superconductor circuit.

The multi-layer board 30 has a substrate 31 that is a plate-shaped organic resin or the same to which a reinforcing material such as a filler of an organic or an inorganic material is mixed, or on which a reinforcing layer is stacked; and wiring layers 21, 22, 23 composed of conductor circuits with prescribed patterns stacked on the substrate 31 and arranged in the XY plane in the diagram.

The superconductor circuit chip 1 has the function of processing data using quantum mechanical phenomena by quantum bits, and has a structure in which a connection portion 12 is provided with a prescribed arrangement on the surface of the substrate 11 (the connection portion need not be a conductor wiring layer forming a circuit pattern as long as it is a conductor that can connect with circuit elements inside the superconductor circuit chip 1). The connection portion 12 is preferably composed of a superconductive material.

More specifically, the substrate 11 is constituted by a material that undergoes little deformation in a superconductive environment, such as silicon (Si), gallium arsenide (GaAs), sapphire, or glass. Additionally, the connection portion 12 making up the quantum bit circuit formed on the substrate 11 is composed of niobium (Nb), a nitride of niobium such as niobium nitride, aluminum (Al), indium (In), lead (Pb), tin (Sn), rhenium (Re), palladium (Pd), titanium (Ti), a nitride of titanium, tantalum (Ta), a nitride of tantalum, or a superconductive alloy containing at least one of the above.

As the metal of the connection portion, aside from the aforementioned superconductive material, the connection portion 12 may, in the present example embodiment, have a metal layer, such as gold (Au), platinum (Pt), or palladium (Pd), on the surface thereof.

As illustrated in FIG. 2A, the wiring layers 21, 22, 23 provided on the substrate 31 of the multi-layer board 30 are constituted by a material such as, for example, copper (Cu) or aluminum (Al), and are formed into prescribed circuit patterns by means such as sputtering, vapor deposition, electroless plating, and electroplating. Additionally, the specific method for forming the conductive material layer on the prescribed circuit pattern may be a subtractive method in which a resist coated on the surface is used as a mask, an additive method in which plating is used, a semi-additive method, a lift-off method in which a pattern is formed by removing a coated resist, etc.

The structure of the pins 40A, 40B, and 40C will be explained in detail with reference to FIG. 3.

As illustrated in FIG. 3, for example, the pin 40A is provided with an upper pin 41 connected to the wiring layers 21, 22, 23, the upper pin 41 being integrally provided, at the proximal end thereof, with a flange 42 having a larger diameter. Multiple types of the upper pins 41 with different lengths are prepared, as in the upper pin 41′ indicated by chain lines in FIG. 3, in accordance with the insertion depths (insertion depths in the Z-axis direction in FIG. 2A and FIG. 2B) of the pins 40A, 40B, 40C into the multi-layer board 30, as illustrated in FIG. 2A, and those with appropriate lengths are selected in accordance with whether they are to be used as the pins 40A, 40B, or 40C. The substrate 31 and the wiring 21, 22, 23 have, pre-formed therein, through-holes (so-called pilot holes) having inner diameters that are slightly larger than the upper pins 41 at positions at which the pins 40A, 40B, 40C are to be inserted.

The lower surface of the flange 42 is provided with a tubular cylinder 43. The cylinder 43 is provided with a retaining portion 44 having a tubular shape with a diameter smaller than the cylinder 43. Additionally, the cylinder 43 supports a lower pin 45 so as to be movable in the axial direction and so as to be movable on the same axis as the upper pin 41, the lower pin 45 being configured so as to be biased downward by elastically deforming a compression spring 46 by moving upward (the Z-axis direction in FIG. 2A and FIG. 2B). Additionally, the proximal end of the lower pin 45 has a large-diameter portion 47, and the length by which it is possible to move downward (the Z-axis direction in FIG. 2A and FIG. 2B) against the bias of the compression spring 46 is restricted at a prescribed position by the large-diameter portion 47 butting against the retaining portion 44.

The pins 40A, 40B, 40C have the same structure, differing only in terms of the length of the upper pin 41. The pin 40A has the longest upper pin 41 and has a length (the length from the flange 42 to the tip of the upper pin 41) such that the tip thereof penetrates through the through-hole 21a and protrudes upward from the highest wiring layer 21 in the multi-layer board 30. The pin 40B has a length (the length from the flange 42 to the tip of the upper pin 41) such as to penetrate through the through-hole 22a and to protrude upward from the second wiring layer 22 from the top in the multi-layer board 30. The pin 40C has a length (the length from the flange 42 to the tip of the upper pin 41) such as to penetrate through the through-hole 23a and to protrude upward from the third wiring layer 23 from the top in the multi-layer board 30.

As illustrated in FIG. 2A, the pin 40A passes through through-holes 22b, 23c having a sufficiently larger diameter than the upper pin 41, formed respectively in the wiring layer 22 and the wiring layer 23, thereby extending to the wiring layer 21 and penetrating through, while plastically deforming, the wiring layer 21, so as to extend above the through-hole 21a.

The pin 40B passes through the through-hole 23b having a sufficiently larger diameter than the upper pin 41, formed in the wiring layer 23, thereby extending to the wiring layer 22 and penetrating through, while plastically deforming, the wiring layer 22, so as to extend above the through-hole 22a.

The pin 40C extends to the lowest wiring layer 23 and penetrates through, while plastically deforming, the wiring layer 23, so as to extend above the through-hole 23a.

In the example in FIG. 2A, the upper pins 41 of the pins 40A, 40B, 40C all penetrate through the wiring layers 21, 22, 23 from the lower surfaces to the upper surfaces. In other words, the tips of the upper pins 41 are inserted to depths such as to protrude from the upper surfaces of the wiring layers 21, 22, 23. However, it is not essential for them to “penetrate” entirely through so as to protrude from the upper surfaces, and they can be expected to have effects of increasing the reliability of electrical contact as long as they are inserted such that at least the tips of the upper pins 41, while plastically deforming or elastically deforming the lower surfaces of the wiring layers 21, 22, 23, protrude from the lower surfaces towards the upper surfaces, have contact surfaces with the wiring layers 21, 22, 23, and generate contact pressure due to elastic deformation with the through-holes 21a, 22a, 23a in the wiring layers 21, 22, 23.

In the multi-layer board 30, a structure in which the through-holes 21a, 22a, 23a are simply formed in the wiring layers 21, 22, 23 was employed. However, through-holes 24a, 25a, 26a as in the modified examples illustrated in FIG. 2B may also be employed.

In other words, the through-holes 24a, 25a, 26a of the modified examples have structures in which plating layers respectively electrically connected to the wiring layers 21, 22, 23 are provided in the substrate 31 making up the multi-layer board 30A. That is, due to the inner surfaces of the through-holes 21a, 22a, 23a being plated, there are conductor plated portions 24a, 25a, 26a electrically connected to the wiring layers 21, 22, 23 and extending to the lower surface of the multi-layer board 30A on at least portions of the through-holes 21a, 22a, 23a, thereby enlarging the contact areas with the pins 40A, 40B, 40C and further increasing the reliability of the electrical connections.

Additionally, the inner diameters of the plated portions 24a, 25a, 26a are set to a negative dimensional tolerance with respect to the outer diameters of the pins 40A, 40B, 40C, so as to plastically deform and elastically deform as the upper pins 41 are inserted, thereby ensuring contact pressure. Additionally, the plated portions 24a, 25a, 26a are all formed to a range extending to the lower surface of the multi-layer board 30A. Thus, the pin 40A need not have a length extending to the wiring layer 24, and likewise, the pin 40B need not have a length extending to the wiring layer 25. It is sufficient for the pins 40A, 40B to have the same length as the shortest pin 40C, which has a length extending to the wiring layer 26. That is, it is possible to use pins 40A, 40B, 40C that are of the same length.

In the superconductor device with the abovementioned configuration, by inserting the upper pins 41 in the multi-layer board 30 (30A) in the thickness direction (the Z-axis direction in the drawing) with the pins 40A, 40B, 40C arranged between the superconductor circuit chip 1 and the multi-layer board 30 (30A), the upper pins 41 are inserted while making them intersect the wiring layers 21 (24), 22 (25), 23 (26), and by making the flanges 42 contact the lower surface of the multi-layer board 30 (30A), the insertion amounts thereof are restricted to prescribed depths and the upper pins 41 can be electrically connected to the wiring layers 21 (24), 22 (25), 23 (26).

The upper pins 41 can electrically connect the pins 40A, 40B, 40C, respectively, to the wiring layers 21 (24), 22 (25), 23 (26), in the example embodiment in FIG. 2A, by being inserted and penetrating through, while plastically deforming, the wiring layers 21, 22, 23, and in the example embodiment in FIG. 2B, by penetrating through, while plastically deforming, the plating layers of the through-holes 24a, 24b, 24c. Additionally, in the example embodiment in FIG. 2B, (the plated portions of) the through-holes 24a, 25a, 26a each extend to the lower surface of the multi-layer board 30A. Therefore, the lengths of the pins 40A, 40B, 40C can be made uniformly the same as that of the shortest pin 40C (having a length sufficient to penetrate through the wiring layer 26).

Additionally, the lower pins 45 of the pins 40A, 40B, 40C are each biased by the compression springs 46 so as to extend the pins 40A, 40B, 40C. Thus, they come into contact with, while deforming, the surface of the wiring layer (connection portion) 12 of the superconductor circuit chip 1, and are electrically connected.

According to the structures described above, the upper ends of the upper pins 41 of the pins 40A, 40B, 40C penetrate through the wiring layers 21, 22, 23 and connect thereto while deforming them in a state in which a prescribed contact area is ensured, and the lower ends of the upper pins 41 of the pins 40A, 40B, 40C are electrically connected with, while deforming, the connection portion 12 of the superconductor circuit chip 1 with a force in accordance with the deformation amount of the compression springs 46.

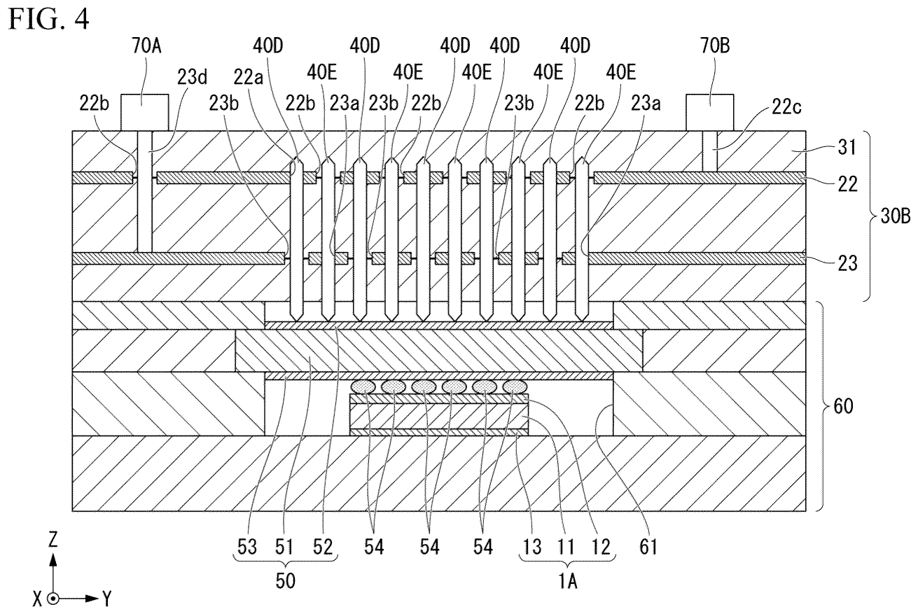

A superconductor device according to a second example embodiment will be explained with reference to FIG. 4. The constituent elements that are the same as those in the first example embodiment will be assigned the same reference numbers and explanations thereof will be simplified.

This superconductor device has a basic structure in which a superconductor circuit chip 1A is connected to a multi-layer board 30B by an interposer 50, with pins 40D, 40E being used to connect the interposer 50 with the multi-layer board 30B. Additionally, the stage 60 accommodates the superconductor circuit chip 1A and the interposer 50, and maintains them at super-low temperatures in which quantum states can be realized.

Additionally, the multi-layer board 30B is provided with connectors 70A, 70B used for connection with external equipment.

The interposer 50 has a structure in which wiring layers 52, 53 are provided on the upper surface and the lower surface of an interposer board 51.

The interposer board 51 is constituted by a material having superconductive properties like the superconductor circuit chip 1A, the material having little deformation in superconductive environments, such as silicon (Si), gallium arsenide (GaAs), sapphire, glass, etc. Additionally, the wiring layers 52, 53 making up the superconductor circuit formed on the interposer board 51 are constituted by niobium (Nb), a nitride of niobium such as niobium nitride, aluminum (Al), indium (In), lead (Pb), tin (Sn), rhenium (Re), palladium (Pd), titanium (Ti), a nitride of titanium, tantalum (Ta), a nitride of tantalum, or a superconductive alloy containing at least one of the above. Additionally, a metal layer such as gold (Au), platinum (Pt), or palladium (Pd) may be formed on the surface thereof.

Additionally, the wiring layer 53 on the lower side of the interposer 50 is connected to a wiring layer (connection portion) 12 in the superconductor circuit chip 1A by bumps 54 constituted by the same superconductor material as the interposer 50.

The multi-layer board 30B is provided with an upper wiring layer 22 and a lower wiring layer 23, and pins 40D, 40E constituted by conductors penetrate through these wiring layers 22, 23.

The wiring layer 22 has through-holes 22a that have inner diameters slightly smaller than the pins 40D, 40E and that contact the pins 40D, 40E in a plastically deformed and/or an elastically deformed state, and through-holes 22b that have inner diameters slightly larger than the pins 40D, 40E and that allow the pins 40D, 40E to pass through in a non-contact state.

The wiring layer 23 has through-holes 23a that have inner diameters slightly smaller than the pins 40D, 40E and that contact the pins 40D, 40E in a plastically deformed and/or an elastically deformed state, and through-holes 23b that have inner diameters slightly larger than the pins 40D, 40E and that allow the pins 40D, 40E to pass through in a non-contact state.

The pins 40D contact the wiring layer 22 at the through-holes 22a, pass through the wiring layer 23 at the through-holes 23b, and contact the wiring layer 52 in the interposer 50, thereby electrically connecting the wiring layer 52 in the interposer 50 with the wiring layer 22. Furthermore, the wiring layer 22 is connected to a connector 70B, forming a circuit that extends from the interposer 50, by way of the wiring layer 52, the pins 40D, the wiring layer 22, and a through-hole via 22c, to the connector 70B.

The pins 40D contact the wiring layer 22 at the through-holes 22a and pass through the wiring layer 23 at the through-holes 23b, thereby electrically connecting the wiring layer 52 in the interposer 50 with the wiring layer 22. Furthermore, the wiring layer 22 is connected to the connector 70B, thereby forming a circuit that extends from the interposer 50, by way of the wiring layer 52, the pins 40D, the wiring layer 23, and the through-hole via 22c, to the connector 70B.

Additionally, the pins 40E contact the wiring layer 23 at the through-holes 23a, pass through the wiring layer 22 at the through-holes 22b, and contact the wiring layer 52 in the interposer 50, thereby electrically connecting the wiring layer 52 in the interposer 50 with the wiring layer 23. Furthermore, the wiring layer 23 is connected to a connector 70A, forming a circuit that extends from the interposer 50, by way of the wiring layer 52, the pins 40E, the wiring layer 23, and a through-hole via 23d, to the connector 70A.

The stage 60 has a cooling function. The stage 60 is a so-called cold stage provided with a milliKelvin [mK] order super-cold temperature refrigerator (not illustrated) that can realize superconductive states in the materials making up the superconductor circuit chip 1A and the interposer 50.

This stage 60 is preferably constituted by, for example, a metal such as copper (Cu), a copper alloy, or aluminum (Al). Since the superconductor phenomena that are utilized occur at super-low temperatures of 9.2 Kelvin [K] or below in the case in which niobium (Nb) is contained as a superconductive material in the superconductor circuit chip 1, and of 1.2 Kelvin [K] or below in the case in which aluminum (Al) is contained, the stage 60 is required to have cooling capacity to realize the super-low temperatures indicated above.

The stage 60 is provided with a recess 61, this recess 61 opening upward and having, for example, a rectangular planar shape corresponding to the planar shapes of the superconductor circuit chip 1 and the interposer 50.

The superconductor circuit chip 1A is accommodated in the recess 61. The superconductor circuit chip 1A has a substrate 11 and a connection portion (wiring layer) 12 on the upper surface thereof, and in the illustrated example, is attached to the recess 61 by an adhesive portion 13 of the upper surface. Instead of the adhesive portion 13, a mechanical attachment means such as mating of recesses/protrusions by means of pins may be employed, or the attachment means may be omitted.

In the superconductor device of the second example embodiment, the superconductor circuit chip 1A and the interposer 50 are united by being connected by means of bumps 54, and are disposed in the recess 61 in the stage 60. Additionally, the superconductor circuit chip 1 can be connected to external equipment by a connector 70A connected to the second wiring layer 23 and by a connector 70B connected to the first wiring layer 22 by making the pins 40D, 40E penetrate through the multi-layer board 30B in the thickness direction (Z-axis direction) so that the lower ends of these pins 40D, 40E contact the wiring layer 52 on the interposer 50, or so that the lower ends of the pins 40D, 40E partially penetrate in a state in which the surface of the wiring layer 52 is deformed.

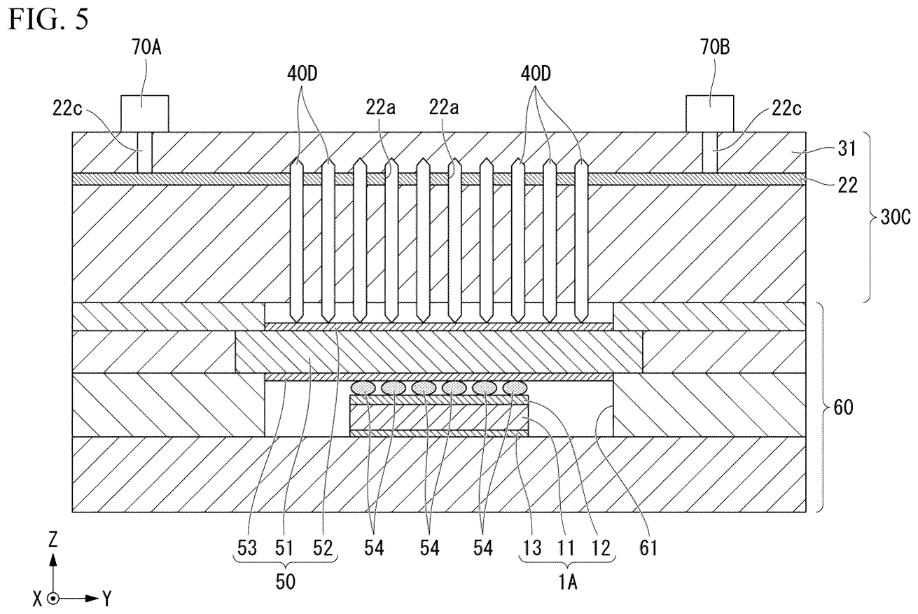

A superconductor device according to a third example embodiment will be explained with reference to FIG. 5. The constituent elements that are the same as those in the first and second example embodiments will be assigned the same reference numbers and explanations thereof will be simplified.

A multi-layer board 30C in the third example embodiment has a single wiring layer 22. The upper ends of pins 40D penetrate through this wiring layer 22, and the lower ends of the pins 40D contact a wiring layer 52 in an interposer 50. Additionally, the wiring layer 22 is connected to connectors 70A, 70B by through-hole vias 22c.

In this third example embodiment, the upper ends of the pins 40D penetrate through the wiring layer 22, thereby contacting the wiring layer 22 in a plastically deformed and elastically deformed state. As a result thereof, the superconductor circuit chip 1A can connect with external equipment by way of the wiring layer 52 in the interposer 50, the pins 40D, the wiring layer 22, the through-hole via 22c, and the connector 70A (70B).

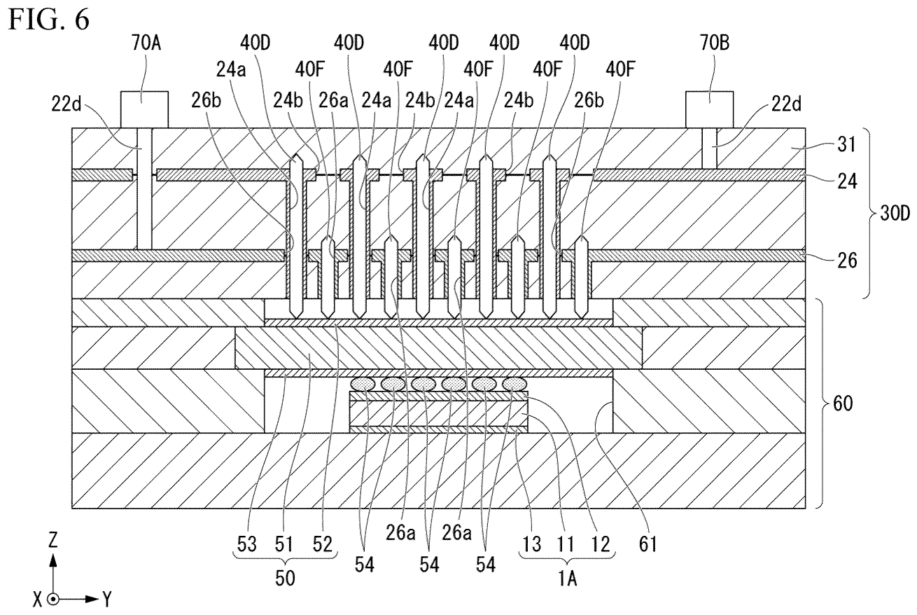

A superconductor device according to a fourth example embodiment will be explained with reference to FIG. 6. The constituent elements that are the same in the first to the fourth example embodiments will be assigned the same reference numbers and explanations thereof will be simplified.

A multi-layer board 30D in the fourth example embodiment has an upper wiring layer 24 and a lower wiring layer 26. The upper ends of pins 40D penetrate through the wiring layer 24, and the lower ends of the pins 40D contact a wiring layer 52 of an interposer 50. The wiring layer 22 is connected to connectors 70A, 70B by way of through-hole vias 22c. The wiring layer 22 has through-holes 24a, the inner surfaces of the through-holes 24a being plated to form plated portions.

Additionally, the upper ends of pins 40F penetrate through the wiring layer 26, and the lower ends of the pins 40F contact the wiring layer 52 in the interposer 50. The wiring layer 26 has through-holes 26a, the inner surfaces of the through-holes 26a being plated to form plated portions.

Furthermore, the wiring layer 26 has through-holes 26a for passing the pins 40D to be connected to the wiring layer 24 above, these through-holes 26a having inner diameters that are sufficiently larger than the outer diameters of the pins 40D. In FIG. 6, the pins 40F have lengths sufficient to penetrate through the wiring layer 26 and do not reach the wiring layer 24 above. However, in order to avoid contacting the wiring layer 24 in the case in which, for example, instead of the pins 40F, longer pins of the same length as the pins 40D which is longer than pin 40F (having lengths sufficient to penetrate through the wiring layer 24) are used, the wiring layer 24 has through-holes 24b having inner diameters larger than the outer diameter of the pins 24F at positions corresponding to the pins 24F.

In the fourth example embodiment, the upper ends of the pins 40D penetrate through the wiring layer 24, thereby contacting plating layers making up the through-holes 24a in the wiring layer 24 in a plastically deformed and elastically deformed state. Thus, the superconductor circuit chip 1A can connect with external equipment by way of the wiring layer 52 in the interposer 50, the pins 40D, the wiring layer 24, the through-hole via 22c, and the connector 70B. Additionally, the upper ends of the pins 40F contact the plating layers making up the through-holes 26a in the wiring layer 26 in a plastically deformed and elastically deformed state. Thus, due to such contact, the superconductor circuit chip 1A can connect with external equipment by way of the wiring layer 52 in the interposer 50, the pins 40F, the wiring layer 26, the through-hole via 22d, and the connector 70A.

According to the configuration described above, the pins 40D and the wiring layer 24 can be electrically connected by way of the through-holes 24a including plating layers, and the pins 40F and the wiring layer 26 can be electrically connected by way of the through-holes 26a including plating layers. These connections can ensure that the contact area and the contact pressure are as large as possible while deforming the plating layers in the through-holes 24a, 26a, thereby allowing the reliability of the electrical connections to be increased.

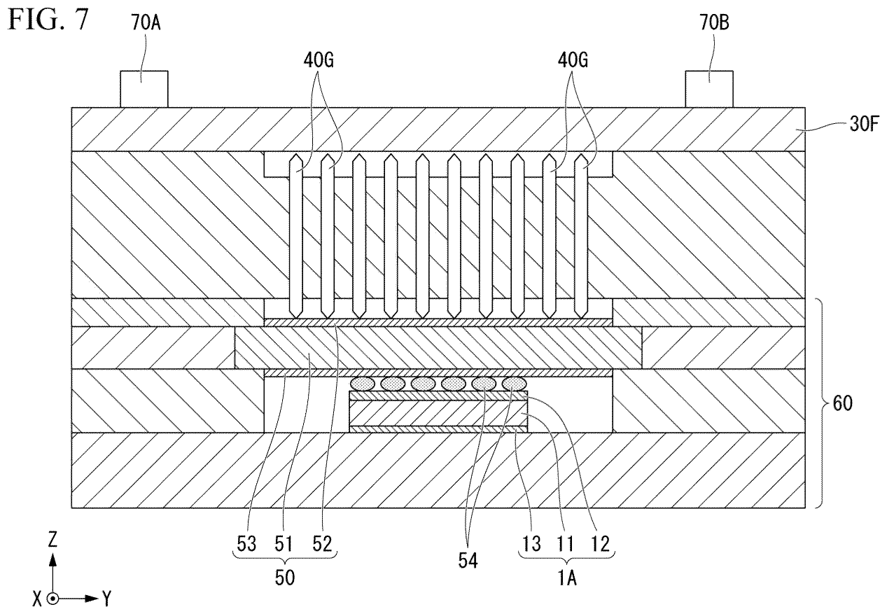

FIG. 7 illustrates a comparative example not provided with the characteristics of the first to fourth example embodiments. The features in the drawing that are the same as those in the example embodiments will be assigned the same reference numbers and explanations thereof will be simplified.

The superconductor device of this comparative example has a structure in which an interposer 50 provided on a superconductor circuit chip 1A and a multi-layer board 30F are electrically connected by pins 40G. More specifically, the lower ends of the pins 40G contact a wiring layer 52 in the interposer 50, and the upper ends of the pins 40G contact a wiring layer (not illustrated) on the lower surface of the multi-layer board 30F.

The multi-layer board 30F, like the respective example embodiments of the present disclosure, has a wiring layer (not illustrated), and the upper ends of the pins 40G contact the wiring layer on the lower surface, thereby connecting the connectors 70A, 70B, which are electrically connected to the wiring layer, to the superconductor circuit chip 1A via the wiring layer, the pins 40G, and the interposer 50.

In this comparative example, thermal expansion and contraction associated with temperature changes from the low temperatures at which superconductive states can be realized in the superconductor circuit chip 1A and the interposer 50 to ambient temperature can change the contact states (contact pressure) between the pins 40G and the wiring layer, and due to the structure in which point contact is made by the tapered portions at the tips of the pins 40G, the contact resistance between the pins 40G and the wiring layer can become excessively high, or they can be put in a non-contact state, thereby causing contact defects. These contact defects are difficult to reliably prevent, even in cases in which, for example, the pins 40G have extendable/retractable structures with internal springs, etc.

In contrast therewith, in the first to the fourth example embodiments, the pins 40A, 40B, etc. penetrate through the wiring layer 21, etc. (including not only cases in which they penetrate completely through in the thickness direction, but also including cases in which they are inserted midway through in the thickness direction) to contact cross-sections of the wiring layer 21, etc., and plastically deformed or elastically deformed locations. Thus, a large contact area can be ensured and a prescribed contact pressure can be ensured, thereby increasing the reliability of the electrical connections.

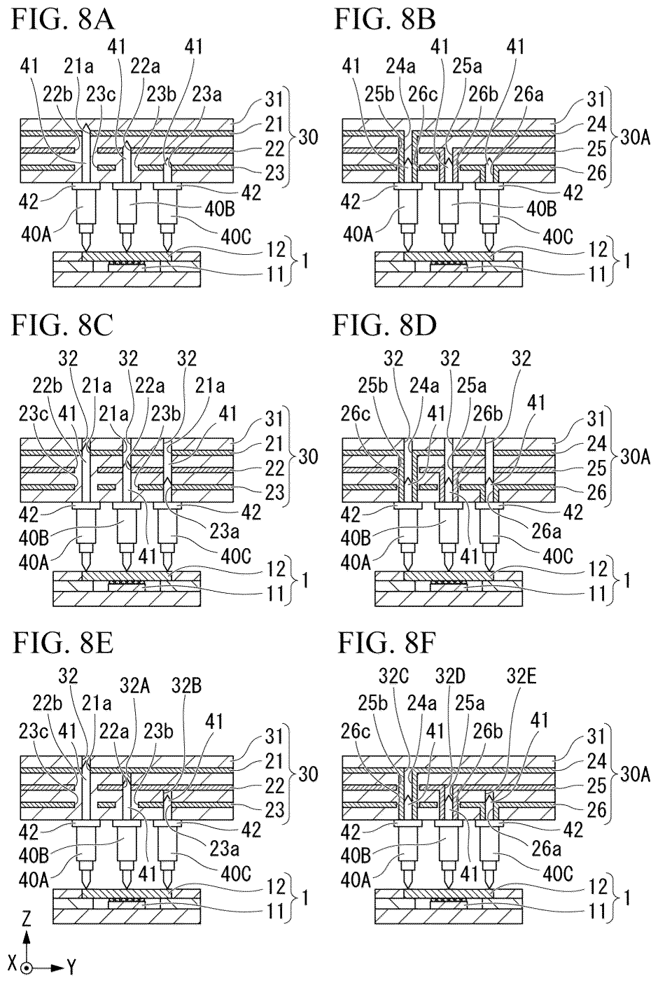

Modified examples of the first example embodiment illustrated in FIG. 2A, FIG. 2B, and FIG. 3 will be explained with reference to FIG. 8A to FIG. 8F. In order to facilitate understanding of the modified examples, a structure that is the same as that in FIG. 2A will be illustrated as basic form 1 in FIG. 8A, and a structure that is the same as that in FIG. 2B will be illustrated as basic form 2 in FIG. 8B.

That is, the superconductor device with the basic form 1 illustrated in FIG. 8A has a basic structure in which the superconductor circuit chip 1 and the multi-layer board 30 are connected by the pins 40A, 40B, 40C.

The multi-layer board 30 has a substrate 31 and wiring layers 21, 22, 23 stacked on the substrate 31.

The superconductor circuit chip 1 illustrated in FIG. 8A has the function of processing data by using quantum mechanical phenomena by quantum bits, and has a structure in which a connection portion 12 is provided, in a prescribed arrangement, on the surface of the substrate 11.

As illustrated in FIG. 8A, the wiring layers 21, 22, 23 provided on the substrate 31 of the multi-layer board 30 are constituted, for example, by materials such as copper (Cu) and aluminum (Al), and form prescribed circuit patterns.

As illustrated in said drawing, multiple types of the upper pins 41 of the pins 40A are prepared, with different lengths in accordance with the insertion depths of the pins 40A, 40B, 40C into the multi-layer board 30, as with the upper pin 41′ indicated by the chain lines in FIG. 3. The tip of the pin 40A has a length (the length from the flange 42 to the tip of the upper pin 41) sufficient to penetrate through a through-hole 21a and to protrude upward from the highest wiring layer 21 in the multi-layer board 30. The pin 40B has a length (the length from the flange 42 to the tip of the upper pin 41) sufficient to penetrate through a through-hole 22a and to protrude upward from the second wiring layer 22 from the top in the multi-layer board 30. The pin 40C has a length (the length from the flange 42 to the tip of the upper pin 41) sufficient to penetrate through a through-hole 23a and to protrude upward from the third wiring layer 23 from the top in the multi-layer board 30.

The through-holes 24a, 25a, 26a in the basic form 2 illustrated in FIG. 8B have structures provided with plated portions respectively electrically connected to the wiring layers 21, 22, 23 on the substrate 31 making up the multi-layer board 30A.

According to the configuration described above, the upper ends of the upper pins 43 of the pins 40A, 40B, 40C penetrate through, while deforming, the wiring layers 21, 22, 23 (more specifically, the plated portions 24a, 25a, 26a on the inner surfaces of the through-holes, which are integrated therewith) and are connected thereto in a state ensuring prescribed contact areas, and the lower ends of the upper pins 43 of the pins 40A, 40B, 40C are electrically connected with, while deforming, the connection portion 12 on the superconductor circuit chip 1 with forces in accordance with the amounts of deformation of the aforementioned compression springs 46.

FIG. 8C illustrates modified example 1. That is, the multi-layer board 30A has a structure provided with through-holes 32, which penetrate through in the up-down direction, regardless of the lengths of the pins 40A, 40B, 40C, at the locations where the pins 40A, 40B, 40C of different lengths are to be inserted. Therefore, the pins 40A, 40B, 40C, in accordance with the lengths thereof, are respectively inserted in the through-holes 32 to near the openings at the upper ends, to the middles, and to near the openings at the lower ends, thereby penetrating through the wiring layers 21, 22, 23 in the through-holes 21a, 22a, 23a.

In modified example 1, through-holes 32 serving as pilot holes for the through-holes 21a, 22a, 23a in the multi-layer board 30 are all made to penetrate through the substrate 31 from the upper surface to the lower surface. In other words, the pilot holes for connecting the respective pins 40A, 40B, 40C with the prescribed wiring layers 21, 22, 23 can be formed without requiring particularly high machining precision for the bore depths of the through-holes 32.

FIG. 8D illustrates modified example 2. That is, the multi-layer board 30A, like modified example 1, has through-holes 32 penetrating through from the upper surface to the lower surface at the locations at which the pins 40A, 40B, 40C are to be inserted. Additionally, below the locations at which these through-holes 32 respectively intersect the wiring layers 21, 22, 23, they have plated portions 24a, 25a, 26a electrically connected to these wiring layers 21, 22, 23. Additionally, since these plated portions 24a, 24b, 24c are formed to the lower surface of the multi-layer board 30A, the lengths of the pins 40A, 40B, 40C are uniformly set to be the same as that of the shortest pin 40C (having a length sufficient to penetrate through the wiring layer 26).

In this modified example 2 also, all of the through-holes 32 serving as pilot holes when forming the plated portions 24a, 25a, 26a in the multi-layer board 30A are made to penetrate through in the up-down direction. In other words, the pins 40A, 40B, 40C configured to have the same length can be connected to the respective wiring layers 21, 22, 23 without requiring particularly high machining precision for the bore depths of the through-holes 32.

FIG. 8E illustrates modified example 3. That is, the multi-layer board 30A has a structure in which through-holes 32, 32A, 32B penetrating in accordance with the depths of wiring layers 21, 22, 23 to be respectively connected are respectively provided at locations at which the pins 40A, 40B, 40C of different lengths are to be inserted, in accordance with the lengths of these pins 40A, 40B, 40C.

Specifically, the through-holes 32 penetrate through all of the wiring layers 21, 22, 23 and extend from the lower surface to the upper surface of the multi-layer board 30, the through-hole 32A penetrating through the wiring layers 22, 23 and extending to an area reaching the lower surface of the wiring layer 21, and the through-hole 32B penetrating through the wiring layer 23 and extending to an area reaching the lower surface of the wiring layer 22.

Additionally, the pins 40A, 40B, 40C respectively penetrate through and are connected with the wiring layers 21, 22, 23 via the through-holes 21a, 22a, 23a in accordance with the lengths thereof.

In this modified example 3, by forming the through-holes 32, 32A, 32B that serve as pilot holes for the through-holes 21a, 22a, 23a in the multi-layer board 30 to respectively prescribed depths, the pins 40A, 40B, 40C of different lengths can respectively connect with the prescribed wiring layers 21, 22, 23.

FIG. 8F illustrates modified example 4. That is, the multi-layer board 30A, like modified example 3, has through-holes 32C, 32D, 32E to prescribed depths at the locations at which the pins 40A, 40B, 40C are to be inserted.

Additionally, below the locations where these through-holes 32C, 32D, 32E respectively intersect the wiring layers 21, 22, 23, they have plated portions 24a, 25a, 26a electrically connected to these wiring layers 21, 22, 23. Additionally, since these plated portions 24a, 24b, 24c are formed to the lower surface of the multi-layer board 30A, the lengths of the pins 40A, 40B, 40C can be uniformly set to be the same as that of the shortest pin 40C (having a length sufficient to penetrate through the wiring layer 26).

In this modified example 4 also, the through-holes 32 that serve as pilot holes when forming the plated portions 24a, 25a, 26a in the multi-layer board 30A penetrate to prescribed depths, and the pins 40A, 40B, 40C configured to have the same length can be connected to the respective wiring layers 21, 22, 23.

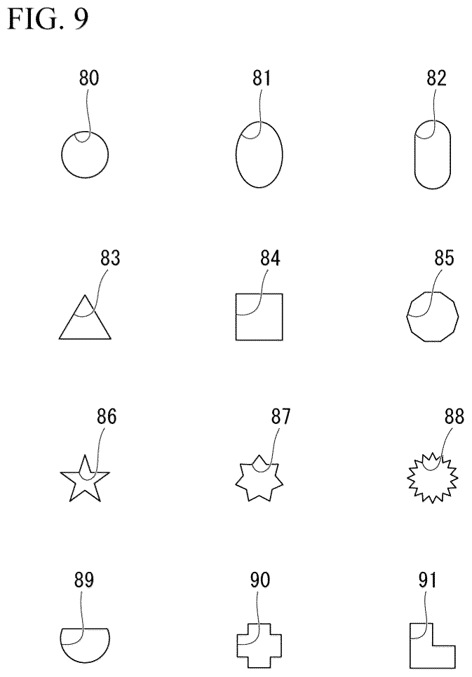

FIG. 9 illustrates modified examples of the transverse cross-sectional shapes of the through-holes (and reflexively, the pins inserted into the through-holes) employed in the first example embodiment and the third example embodiment.

Generally, the through-holes 21a, 22a, 23a and the pins 40A, 40B, 40C, 40D, 40E, 40F constituted by a metal, etc. are provided with perfectly circular transverse cross-sections in consideration of the ease of fabrication when machining them to the prescribed shapes. However, since they are perfectly circle, the contact areas with the wiring layers 24, 25, 26 are minimized at the through portions. Therefore, employing shapes other than perfect circles to enlarge the contact areas is also effective for obtaining stable electrical connections.

Reference number 80 illustrates a perfect circle, which is the same basic shape as that of the through-holes 21a, etc.

Reference number 81 illustrates an ellipse as modified example 1.

Reference number 82 illustrates an oval as modified example 2.

Reference numbers 83 to 85 illustrate modified examples 3 to 5, which are polygonal, reference number 83 illustrating a triangle, reference number 84 illustrating a rectangle (square), and reference number 85 illustrating an octagon.

Reference numbers 86 to 88 illustrate modified examples 6 to 8, which are star-shaped polygons (projected shapes obtained by superimposing polygons with shifted vertices), reference numbers 86, 87, and 88 illustrating, respectively, a star shape 1, a star shape 2, and a star shape 3.

Reference numbers 89 to 91 further illustrate other modified examples 9 to 11, reference number 89 illustrating a semicircle, reference number 90 illustrating a cross, and reference number 91 illustrating an L shape.

According to these modified examples 1 to 11, the contact areas between the through-holes 21a, 22a, 23a and the pins 40A, 40B, 40C, 40D, 40E, 40F can be made larger than that in the case in which the through-holes are perfect circles.

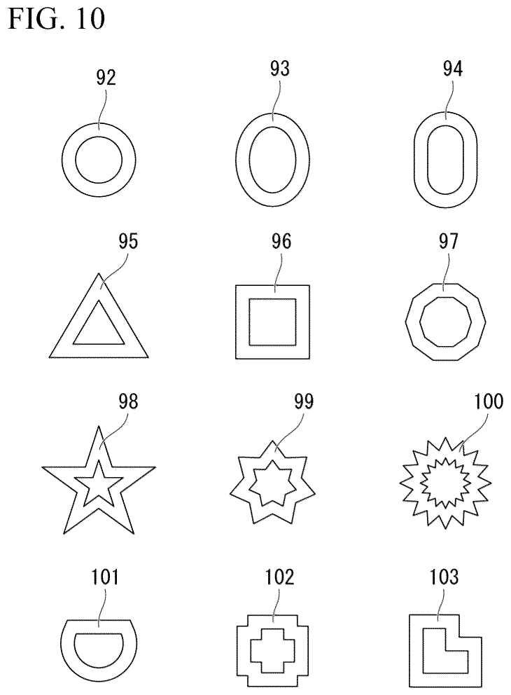

FIG. 10 illustrates modified examples of the transverse cross-sectional shapes of the plated portions (and reflexively, the pins inserted in the through-holes) employed in the second example embodiment and the fourth example embodiment.

Reference number 92 illustrates a perfect circle, which is the same basic shape as that of the plated portions 24a, etc.

Reference number 93 illustrates an ellipse as modified example 1.

Reference number 94 illustrates an oval as modified example 2.

Reference numbers 95 to 97 illustrate modified examples 3 to 5, which are polygonal, reference number 95 illustrating a triangle, reference number 96 illustrating a rectangle (square), and reference number 97 illustrating an octagon.

Reference numbers 98 to 100 illustrate modified examples 6 to 8, which are star-shaped polygons (projected shapes obtained by superimposing polygons with shifted vertices), reference numbers 98, 99, and 100 illustrating, respectively, a star shape 1, a star shape 2, and a star shape 3.

Reference numbers 101 to 103 further illustrate star-shaped polygons, which are other modified examples 9 to 11, reference number 101 illustrating a semicircle, reference number 102 illustrating a cross, and reference number 103 illustrating an L shape.

According to these modified examples 1 to 11, the contact areas between the plated portions 24a, 25a, 26a serving as the through-holes and the pins 40A, 40B, 40C, 40D, 40E, 40F can be made larger than that in the case in which the through-holes are perfect circles.

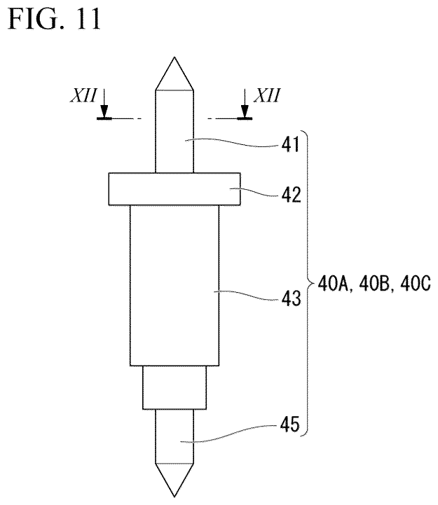

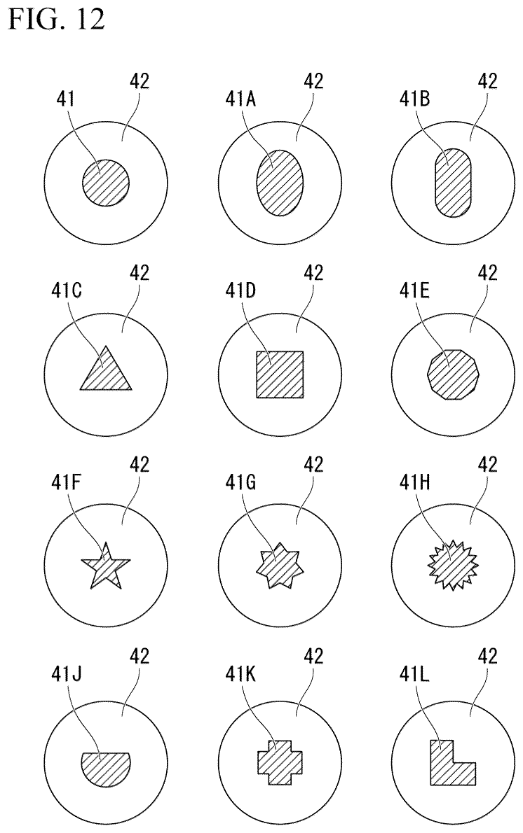

FIGS. 11 and 12 illustrate upper pins 41A to 41L of the pins according to modified examples corresponding to the modified examples of the through-holes illustrated in FIGS. 9 and 10.

Reference number 41 illustrates a perfect circle, which is the same basic shape as that in the first example embodiment to the fourth example embodiment.

Reference number 41A illustrates an ellipse as modified example 1.

Reference number 41B illustrates an oval as modified example 2.

Reference numbers 41C to 41E illustrate modified examples 3 to 5, which are polygonal, reference number 41C illustrating a triangle, reference number 41D illustrating a rectangle (square), and reference number 41E illustrating an octagon.

Reference numbers 41F to 41H illustrate modified examples 6 to 8, which are star-shaped polygons (projected shapes obtained by superimposing polygons with shifted vertices), reference numbers 41F, 41G, and 41H illustrating, respectively, a star shape 1, a star shape 2, and a star shape 3.

Reference numbers 41J to 41L further illustrate other modified examples 9 to 11, reference number 41J illustrating a semicircle, reference number 41K illustrating a cross, and reference number 41L illustrating an L shape.

According to these modified examples 1 to 11, the contact areas between the through-holes 21a, 22a, 23a and the pins 40A, 40B, 40C, 40D, 40E, 40F can be made larger than that in the case in which the upper pins 41 and 41A to 41L are perfect circles.

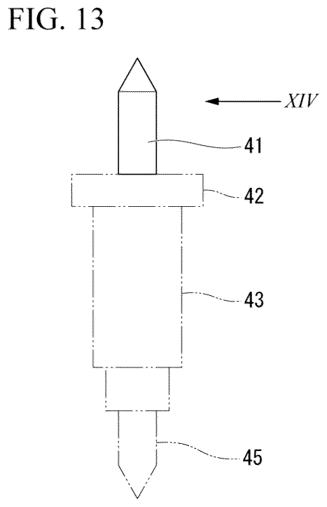

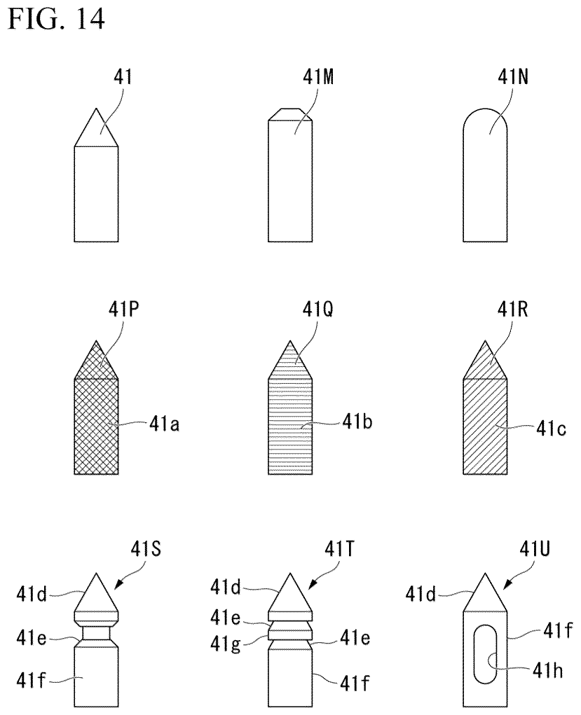

FIGS. 13 and 14 illustrate upper pins 41 and 41M to 41U of pins according to modified examples corresponding to the modified examples of the through-holes illustrated in FIGS. 9 and 10.

Reference number 41 illustrates a conical upper pin that is a basic form similar to the first example embodiment to the fourth example embodiment.

Reference number 41M is an upper pin according to modified example 1, this upper pin 41M having a tip with a flat truncated conical structure. With this upper pin 41M, the contact area with the wiring layer 21, etc. can be enlarged because the tip is planar and there is a portion with a conical surface contiguous with the tip. Thus, the contact area with the wiring layer 21, etc. can be enlarged.

Reference number 41N is an upper pin according to modified example 2, this upper pin 41N including a tip with a spherical surface. With this upper pin 41N, since the tip has a spherical surface shape, it can be brought into tight contact while deforming the wiring layer 21, etc. along the spherical surface, thereby allowing a stable contact state to be maintained.

Reference number 41P is an upper pin according to modified example 3, this upper pin 41P including, on the surface thereof, grooves 41a that are inclined in one direction and in another direction with respect to the axis of the upper pin 41P. With this upper pin 41P, the metal making up the wiring layer 21, etc. plastically deforms or elastically deforms so as to bite into the recesses and protrusions of the grooves 41a, thereby allowing a stable contact state to be maintained.

Reference number 41Q is an upper pin according to modified example 4, this upper pin 41Q including, on the surface thereof, circumferential grooves 41b that are transverse to the axis of the upper pin 41Q. With this upper pin 41Q, the metal making up the wiring layer 21, etc. plastically deforms or elastically deforms so as to bite into the recesses and protrusions of the grooves 41b, thereby allowing a stable contact state to be maintained.

Reference number 41R is an upper pin according to modified example 5, this upper pin 41R including, on the surface thereof, grooves 41c that are inclined in one direction with respect to the axis of the upper pin 41R. With this upper pin 41R, the metal making up the wiring layer 21, etc. plastically deforms or elastically deforms so as to bite into the recesses and protrusions of the grooves 41c, thereby allowing a stable contact state to be maintained.

Reference number 41S is an upper pin according to modified example 6, this upper pin 41S having a structure in which a narrow portion 41e with a smaller diameter than a conical tip 41d and a cylindrical base 41f is provided therebetween.

With this modified example 6, due to the narrow portion 41e deforming when the tip 41d penetrates through the wiring layer 21, etc., it is possible to adapt to cases in which the direction of application of force to the pin 40A, etc. is offset from the direction of the through-hole 21a, etc. Additionally, by inserting the tip 41d until it reaches above the upper surface of the wiring layer 21 and the narrow portion 41e is disposed at the same position as the through-hole 21a, etc., there is a retaining effect on the tip 41d.

Reference number 41T is an upper pin according to modified example 7, this upper pin 41T having a structure in which two narrow portions 41e with a smaller diameter than a conical tip 41d and a cylindrical base 41f are provided therebetween, and a middle portion 41g is provided between these two narrow portions 41e.

With this modified example 7, as with modified example 6, due to the two narrow portions 41e each deforming when the tip 41d penetrates through the wiring layer 21, etc., it is possible to flexibly adapt to cases in which the direction of application of force to the pin 40A, etc. is offset from the direction of the through-hole 21a, etc.

Additionally, by inserting the tip 41d or the middle portion 41g until it reaches above the upper surface of the wiring layer 21 and one of the two narrow portions 41e is disposed at the same position as the through-hole 21a, etc., there is a retaining effect on the tip 41d or the middle portion 41g.

Reference number 41U is an upper pin according to modified example 8, this upper pin 41U being provided with an elongated hole 41h in a cylindrical base 41f that is integrated with a conical tip 41d.

With this modified example 8, the base 41f is provided with the elongated hole 41h. Therefore, the base 41f can easily deform in comparison with the case in which it is solid, and by contacting the wiring layer 21 in the deformed state, the contact pressure can be increased.

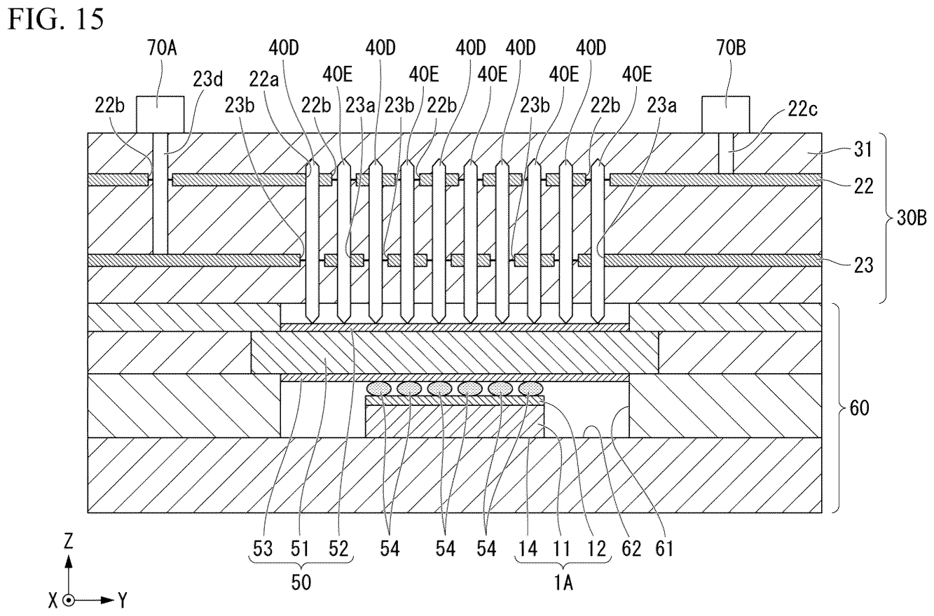

FIG. 15 illustrates a superconductor device according to a fifth example embodiment.

In the superconductor device according to this fifth example embodiment, a lower surface 14 of a superconductor circuit chip 1A contacts a stage 60, which has a cooling function. For example, in the present fifth example embodiment, a recess 61 is formed in the stage 60. The upper surface 62 of the recess 61 is, for example, a bottom surface facing in the Z-axis direction. The recess 61 opens in the Z-axis direction, and when viewed from above, the recess 61 and the upper surface 62 have, for example, rectangular shapes.

The superconductor circuit chip 1A has a smaller planar shape than the recess 61, and the lower surface 14 thereof contacts the upper surface 62 of the recess 61.

A portion of the interposer 50 that contacts the stand 60 does not need to have a wiring layer 53 formed thereon, or a wiring layer 53 may be formed on the portion contacting the stand 60 if an insulating film is formed in order to prevent electrical conduction with the stage 60.

With the superconductor device of the present fifth example embodiment, at least a portion of the interposer 50 is made to contact the stage 60. As a result thereof, by using the interposer 50 as a heat channel, the quantum circuits in the superconductor circuit chip 1A can be cooled to make use of superconductor phenomena.

Additionally, the superconductor circuit chip 1A is disposed inside the stage 60 having a cooling function, and the lower surface 14 thereof contacts the bottom surface of the recess 61 in the stage 60 without an adhesive portion interposed therebetween.

At least a portion of the lower surface 14 may contact a portion of the inner surface of the recess 61. By using such a configuration, cooling can be performed by heat conduction due to direct contact between the superconductor circuit chip 1A and the upper surface 62 of the recess 61 in the stage 60, thereby increasing the cooling performance. Thus, the operations of the quantum circuit in the superconductor circuit chip 1A can be stabilized. Additionally, since the lower surface 14 of the superconductor circuit chip 1A only contacts the upper surface 62 of the recess 61, the superconductor circuit chip 1A can move over the X-Y plane in FIG. 15, and stress and strain due to contraction differences between the superconductor circuit chip 1A and the stage 60 caused by temperature changes to super-low temperatures can be suppressed.

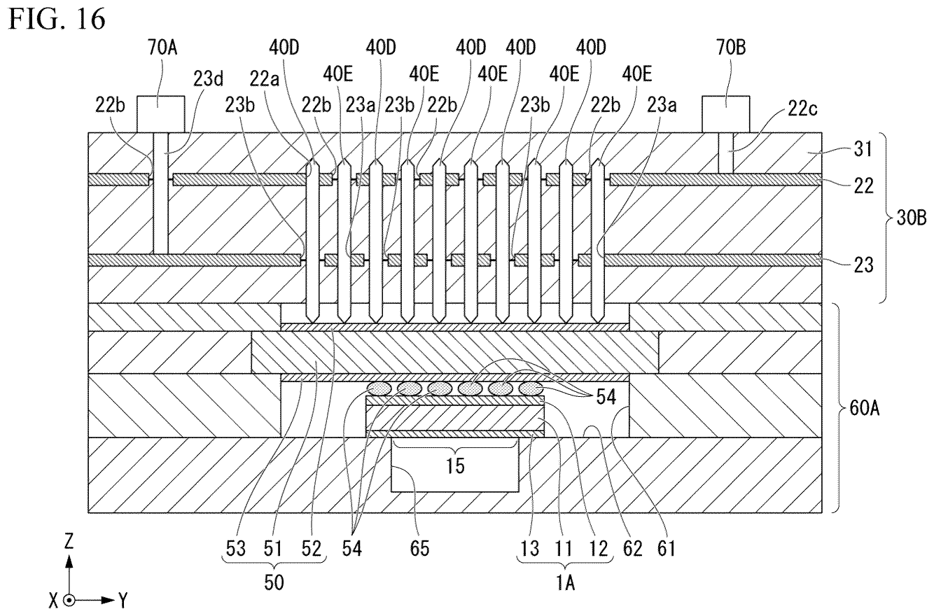

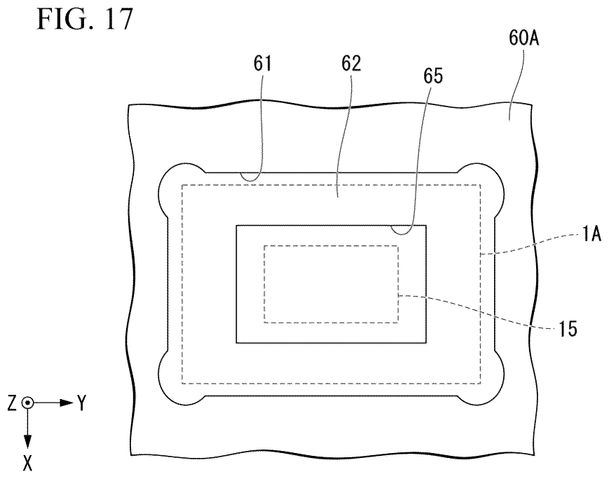

FIGS. 16 and 17 illustrate a superconductor device according to a sixth example embodiment.

The superconductor device according to the present sixth example embodiment, as illustrated in section view in FIG. 16 and in plan view in FIG. 17, has a depression 65 formed by counterbore-machining, etc. on the lower surface 62 of the recess 61 in the stage 60A.

As illustrated in FIG. 17, the region in which the depression 65 is located, as viewed from above (in the Z direction in FIGS. 16 and 17), is larger than the region 15 surrounding the region in which the quantum circuits are formed in the superconductor circuit chip 1A. Thus, the region 15 is contained within the inner side of the region in which the depression 65 is located. The peripheral portions of the lower surface of the superconductor circuit chip 1A may contact the bottom of the recess 61. Therefore, the central portion of the lower surface of the superconductor circuit chip 1A covers the depression 65 and a portion surrounding the central portion of the lower surface contacts a part of the lower surface 62 of the stand 60A.

With the superconductor device of the present sixth example embodiment, as viewed from above, the region of the depression 65 is larger than the region 15 in which the quantum circuits are formed (more specifically, the region that is the outer extent of the region in which the quantum circuits are formed). Thus, the distance between the region 15 in which the quantum circuits are formed and the stage 60A constituted by a material including a metal, etc. can be made large. As a result thereof, the formation of virtual capacitors by the conductor circuits facing each other between one conductor and another can be suppressed, and the influence of resonance occurring in the substrate 11, such as silicon, of the superconductor circuit chip 1A can be reduced. Thus, the influence on the operating frequency of the superconductor circuit chip 1A can be reduced.

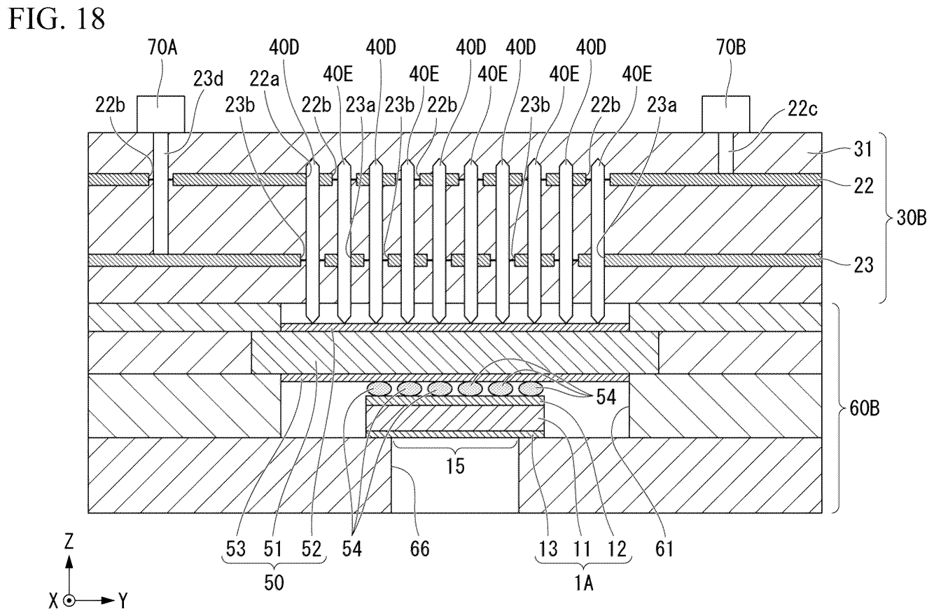

FIG. 18 illustrates a superconductor device according to a seventh example embodiment.

The present seventh example embodiment has a through-hole 66 in the bottom of a recess 11 in a stage 60B. FIG. 18 is a section view illustrating the through-hole 66 formed in the bottom of the recess 61 in the stage 60B according to the seventh example embodiment.

As illustrated in FIG. 18, in the superconductor device of the seventh embodiment, a through-hole 66 is formed in the bottom of the recess 61. As in the case of FIG. 17 relating to the sixth example embodiment, as viewed from above, the region of the through-hole 66 is larger than the region 15 in which the quantum circuits are formed. Thus, the region 15 in which the quantum circuits are formed is contained within the inner side of the region of the through-hole 66. Therefore, the peripheral portions of the lower surface 14 of the superconductor circuit chip 1A may contact the bottom of the recess 61, and may be adhered to or welded to the bottom of the recess 61. Therefore, the central portion of the lower surface 14 of the superconductor circuit chip 1A covers the through-hole 66.

With the superconductor device of the seventh example embodiment, as viewed from above, the region of the through-hole 66 is larger than the region 15 in which the quantum circuits are formed. Thus, the distance between the region 15 in which the quantum circuits are formed and the stage 60A constituted by a material including a metal, etc. can be made large. As a result thereof, the influence of resonance occurring in the substrate, such as silicon, of the chip board 15 can be reduced. Thus, the influence on the operating frequency of the superconductor circuit chip 1A can be reduced.

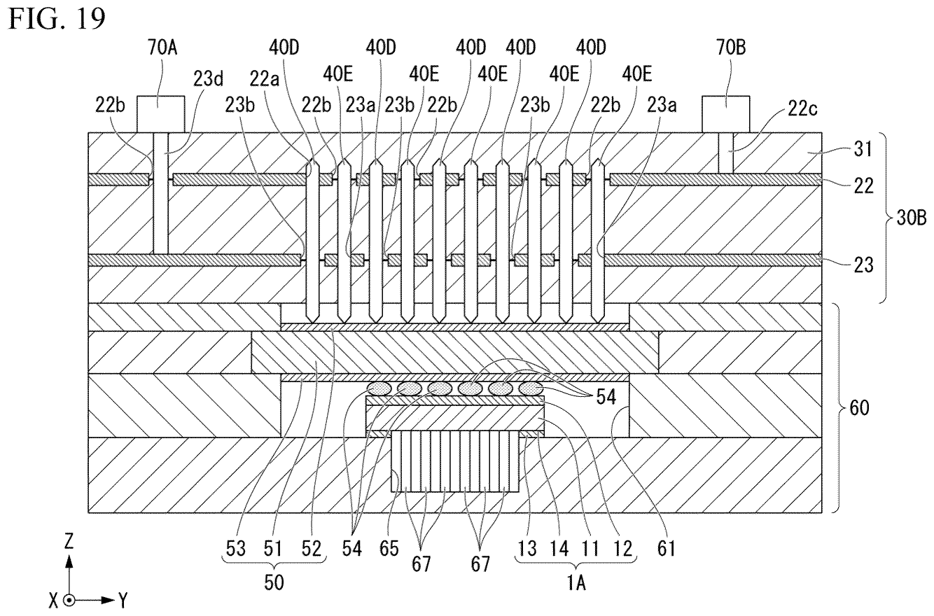

FIG. 19 illustrates a superconductor device according to an eighth example embodiment.

The present eighth example embodiment has pillars 67 in a depression 65 in a recess 61. FIG. 19 is a section view illustrating the depression 65 and the pillars 67 formed in the bottom of the recess 61 in a stage 60C according to the eighth example embodiment.

As illustrated in FIG. 19, a depression 65 is formed in the bottom of the recess 61 in the superconductor device of the eighth example embodiment. Furthermore, the depression 65 is provided with one or more pillars 67. The pillars 67 extend in the direction orthogonal to the lower surface 14 of the superconductor circuit chip 1A and the lower surface 62 of the stage 60 (the XY plane in the drawing).

The pillars 67, at one end, are connected to the bottom of the depression 65, and the pillars 67, at the other end, contact the lower surface 14 of the superconductor circuit chip 1A. Thus, the superconductor circuit chip 1A contacts the pillars 67, which extend from the bottom of the depression 65 in the direction orthogonal to the lower surface 14 of the superconductor circuit chip 1A. The pillars 67 may be cylindrical or may be post-shaped. The pillars 67 are constituted, for example, by a normally conductive material similar to or different from that of the wiring in the interposer 50, by a superconductive material, or by a ceramic material with high thermal conductivity. The one or more pillars 67 may be adhered by an adhesive layer, or may be welded by a metal layer to the lower surface 14 of the superconductor circuit chip 1A.

In the eighth example embodiment, as viewed from above, the region of the depression 65 is larger than the region in which the quantum circuits are formed. Thus, the distance between the region in which the quantum circuits are formed and the stage 60 containing a metal, etc. can be made large. As a result thereof, the influence of resonance occurring in the substrate 11, such as silicon, of the superconductor circuit chip 1A can be reduced. Thus, the influence on the operating frequency of the superconductor circuit chip 1A can be reduced. In addition thereto, the pillars 67 contact the lower surface 14 of the superconductor circuit chip 1A and can directly conduct heat with respect to the superconductor circuit chip 1A, thereby improving the cooling performance.

The pillars 67 may be movable from the bottom of the depression 65 in the up-down (Z axis) direction. Additionally, the positions, shapes, and number of the depression 65 and the through-hole 66 can be changed in accordance with the range over which the quantum circuits in the superconductor circuit chip 1A are formed. Additionally, the positions, number, and lengths of the pillars 67 may also be changed.

The specific configurations of constituent elements of the superconductor device, such as the number and distribution range of wiring layers making up the multi-layer board, and the number and lengths of the pins and the through-holes, are not limited to those in the example embodiments described above.

While example embodiments of the present disclosure have been explained in detail with reference to the drawings above, the specific configurations are not limited to those of these example embodiments, and design modifications, etc. within a range not departing from the spirit of the present disclosure are included.

Additionally, the superconductor device of the present disclosure may also be used in other devices making use of superconductivity. Examples thereof include magnetic field sensors, memory, amplifiers, etc.

As mentioned above, in a superconductor device formed by mounting a superconductor circuit chip making use of quantum states on a circuit board, high reliability of the electrical connections between the superconductor circuit chip (or an interposer on which the superconductor circuit chip is mounted) and the circuit board, etc. is required in the low-temperature environments for realizing the superconductive state. However, if mercury is used, even partially, as the constituent material in an electronic component, measures are needed to prevent the dispersion of mercury into the natural environment in each stage of production, use, and disposal of the electronic components. For this reason, the development of technology for increasing the reliability of electrical connections in the superconductive state without using mercury as a constituent material of the electronic components has been desired.

According to the present disclosure, for example, connections between components in the superconductor device can be maintained in a superconductive environment without using mercury.

Some or all of the above-mentioned example embodiments can be described as in the Supplementary notes below. However, there is no limitation to the example embodiments specified in the Supplementary notes.

### (Supplementary Note 1)

A superconductor device that makes use of superconductive properties, the superconductor device comprising: a superconductor circuit chip in which a functional circuit is provided; a multi-layer board including multiple wiring layers; and multiple pins electrically connecting the superconductor circuit chip with the multi-layer board; wherein the multiple pins are inserted into a wiring layer of the multiple wiring layers in the multi-layer board in a direction intersecting the wiring layer.

### (Supplementary Note 2)

A superconductor device that makes use of superconductive properties, the superconductor device comprising: a superconductor circuit chip in which a functional circuit is provided; a multi-layer board including multiple wiring layers; an interposer that is disposed between the multi-layer board and the superconductor circuit chip, that is electrically connected to the superconductor circuit chip, and that has a wiring layer connected to a wiring layer of multiple wiring layers in the multi-layer board; and multiple pins electrically connecting the interposer with the multi-layer board; wherein the multiple pins are inserted into at least one of the wiring layer in the multi-layer board and the wiring layer in the interposer in a direction intersecting the wiring layer.

### (Supplementary Note 3)

The superconductor device according to either Supplementary note 1 or 2, wherein the pins are electrically connected to one or more of wiring layers in the multi-layer board.

### (Supplementary Note 4)

The superconductor device according to any one of Supplementary notes 1 to 3, wherein the pins can be extended and retracted in a lengthwise direction.

### (Supplementary Note 5)

The superconductor device according to any one of Supplementary note 1 to 4, wherein, in a region in which the multiple pins are inserted, at least a portion of the region contacts the multi-layer board or the superconductor circuit chip.

### (Supplementary Note 6)

The superconductor device according to any one of Supplementary note 1 to 5, wherein the multi-layer board into which the multiple pins are inserted is provided with the multiple wiring layers, and portions of the multiple wiring layers have through-holes, through which a pin passes, having diameters larger than the pin.

### (Supplementary Note 7)

The superconductor device according to any one of Supplementary notes 1 to 6, wherein the multi-layer board comprises multiple wiring layers in the insertion direction of the multiple pins, and at least one of the multiple pins has a length, in the insertion direction, different from other pins.

### (Supplementary Note 8)

The superconductor device according to any one of Supplementary notes 1 to 7, wherein the wiring layers have plated portions that surround the through-holes into which the multiple pins are inserted and that are composed of a conductive material that is integrated with the conductive material making up the wiring layers.

### (Supplementary Note 9)

The superconductor device according to Supplementary note 8, wherein the wiring layers are provided across multiple layers in a thickness direction of the multi-layer board, and the plated portions are formed on the entire inner surfaces of through-holes from one wiring layer to one surface of the multi-layer board.

### (Supplementary Note 10)

The superconductor device according to any one of Supplementary notes 1 to 9, wherein the through-holes have transverse cross-sections that are perfectly circular.

### (supplementary Note 11)

The superconductor device according to any one of Supplementary notes 1 to 10, wherein the multiple pins have transverse cross-sections that are perfectly circular.

### (Supplementary Note 12)

The superconductor device according to any one of Supplementary notes 1 to 9, wherein the through-holes have transverse cross-sections that are not perfectly circular.

### (Supplementary Note 13)

The superconductor device according to any one of Supplementary notes 1 to 9 and 12, wherein the multiple pins have transverse cross-sections that are not perfectly circular.

### (Supplementary Note 14)

The superconductor device according to any one of Supplementary notes 1 to 13, including recessed/protruding grooves on the surfaces of the multiple pins.

### (Supplementary Note 15)

The superconductor device according to any one of Supplementary notes 1 to 14, including holes transversely penetrating through the multiple pins.

### (Supplementary Note 16)

The superconductor device according to any one of Supplementary notes 1 to 15, provided with a stage that is provided with a recess for housing either one of the superconductor circuit chip according to Supplementary note 1, and the superconductor circuit chip and the interposer according to Supplementary note 2, and that cools the superconductor circuit chip and/or the interposer housed therein, wherein the stage is configured so that the recess in the stage contacts the lower surface of the superconductor circuit chip.

### (Supplementary Note 17)

The superconductor device according to any one of Supplementary notes 1 to 16, wherein a surface of the superconductor circuit and an inner surface of the recess in the stage are in direct contact.

### (Supplementary Note 18)

The superconductor device according to any one of Supplementary notes 1 to 16, wherein a surface of the superconductor circuit and an inner surface of the recess in the stage are in contact by an adhesive layer.

### (Supplementary Note 19)

The superconductor device according to Supplementary note 16, wherein the recess in the stage is provided with a counterbore-shaped recess in a bottom thereof, and the recess opens towards a quantum circuit in the superconductor circuit chip.

### (Supplementary Note 20)

The superconductor device according to Supplementary note 19, wherein the counterbore-shaped recess has a pillar that conducts heat between the counterbore-shaped recess and a lower surface of the superconductor circuit chip.

### (Supplementary Note 21)

The superconductor device according to Supplementary note 16, wherein the recess in the stage is provided with a through-hole that penetrates through a bottom thereof, wherein the through-hole opens towards a quantum circuit in the superconductor circuit chip.

### (Supplementary Note 22)

A method for producing a superconductor device in which a superconductor circuit chip provided with a functional circuit that makes use of superconductive properties and a multi-layer board including multiple wiring layers are electrically connected by multiple pins, wherein: the multiple pins are inserted into a wiring layer of the multiple wiring layers in the multi-layer board in a direction intersecting the wiring layer, thereby deforming the wiring layer.

### (Supplementary Note 23)

A method for producing a superconductor device in which an interposer electrically connected to a superconductor circuit chip provided with a functional circuit that makes use of superconductive properties and a multi-layer board including multiple wiring layers are electrically connected by multiple pins, wherein: the multiple pins are inserted into at least one of a wiring layer of the multiple wiring layers in the multi-layer board and a wiring layer in the interposer in a direction intersecting the wiring layer, thereby deforming the wiring layer.

### INDUSTRIAL APPLICABILITY

The present disclosure can, as one example, be used in a superconductor device and a method for production thereof.

While preferred example embodiments of the disclosure have been described and illustrated above, it should be understood that these are exemplary of the disclosure and are not to be considered as limiting. Additions, omissions, substitutions, and other modifications can be made without departing from the spirit or scope of the present disclosure. Accordingly, the disclosure is not to be considered as being limited by the foregoing description, and is only limited by the scope of the appended claims.

What is claimed is:

1. A superconductor device that makes use of superconductive properties, the superconductor device comprising:
a superconductor circuit chip in which a functional circuit is provided;
a multi-layer board including multiple wiring layers; and
multiple pins electrically connecting the superconductor circuit chip with the multi-layer board;
wherein the multiple pins are inserted into a wiring layer of the multiple wiring layers in the multi-layer board in a direction intersecting the wiring layer.

2. The superconductor device according to claim 1, wherein the pins are electrically connected to one or more of wiring layers in the multi-layer board.

3. The superconductor device according to claim 1, wherein the pins can be extended and retracted in a lengthwise direction.

4. The superconductor device according to claim 1, wherein, in a region in which the multiple pins are inserted, at least a portion of the region contacts the multi-layer board or the superconductor circuit chip.

5. The superconductor device according to claim 1, wherein the multi-layer board into which the multiple pins are inserted is provided with the multiple wiring layers, and portions of the multiple wiring layers have through-holes, through which a pin passes, having diameters larger than the pin.

6. The superconductor device according to claim 1, wherein the multi-layer board comprises multiple wiring layers in the insertion direction of the multiple pins, and at least one of the multiple pins has a length, in the insertion direction, different from other pins.

7. A superconductor device that makes use of superconductive properties, the superconductor device comprising:
a superconductor circuit chip in which a functional circuit is provided;
a multi-layer board including multiple wiring layers;
an interposer that is disposed between the multi-layer board and the superconductor circuit chip, that is electrically connected to the superconductor circuit chip, and that has a wiring layer connected to a wiring layer of multiple wiring layers in the multi-layer board; and
multiple pins electrically connecting the interposer with the multi-layer board;
wherein the multiple pins are inserted into at least one of the wiring layer in the multi-layer board and the wiring layer in the interposer in a direction intersecting the wiring layer.

8. The superconductor device according to claim 7, wherein the pins are electrically connected to one or more of wiring layers in the multi-layer board.

9. The superconductor device according to claim 7, wherein the pins can be extended and retracted in a lengthwise direction.

10. The superconductor device according to claim 7, wherein, in a region in which the multiple pins are inserted, at least a portion of the region contacts the multi-layer board or the superconductor circuit chip.

11. The superconductor device according to claim 7, wherein the multi-layer board into which the multiple pins are inserted is provided with the multiple wiring layers, and portions of the multiple wiring layers have through-holes, through which a pin passes, having diameters larger than the pin.

12. The superconductor device according to claim 7, wherein the multi-layer board comprises multiple wiring layers in the insertion direction of the multiple pins, and at least one of the multiple pins has a length, in the insertion direction, different from other pins.

13. A method for producing a superconductor device in which a superconductor circuit chip provided with a functional circuit that makes use of superconductive properties and a multi-layer board including multiple wiring layers are electrically connected by multiple pins, wherein:
the multiple pins are inserted into a wiring layer of the multiple wiring layers in the multi-layer board in a direction intersecting the wiring layer, thereby deforming the wiring layer.
